(19) United States
(12) Patent Application Publication
(10) Pub. No.: US 2011/0163789 A1
(43) Pub. Date: Jul. 7, 2011

(54) DUTY CYCLE CORRECTION CIRCUIT AND METHOD FOR CORRECTING DUTY CYCLE AND SEMICONDUCTOR DEVICE INCLUDING THE DUTY CYCLE CORRECTION CIRCUIT

(76) Inventors: Tae-Sik Na, Seoul (KR); Seok-Hun Hyun, Seongnam-si (KR)

(21) Appl. No.: 12/816,581

(22) Filed: Jun. 16, 2010

(30) Foreign Application Priority Data
Jan. 6, 2010 (KR) 10-2010-0000996

(51) Int. Cl. H03K 3/017

(52) U.S. Cl. 327/175

(57) ABSTRACT

Provided are a duty cycle correction circuit and method for correcting a duty cycle, and a semiconductor device including the duty cycle correction circuit. The duty cycle correction circuit includes a code generator configured to generate a first and a second duty code for adjusting the duty cycle of a clock to a target duty cycle, and a duty cycle corrector including a plurality of inverter circuits connected in series and whose driving capabilities are adjusted in response to the first and second duty code, wherein the duty cycle corrector is configured to correct the duty cycle of the clock based on the driving capabilities of the inverter circuits and to output a corrected clock.

### PRIORITY STATEMENT

This application claims the benefit of priority under 35 U.S.C. §119 from Korean Patent Application No. 10-2010-0000996, filed in the Korean Intellectual Property Office on Jan. 6, 2010, the contents of which are incorporated herein by reference in their entirety.

### BACKGROUND

1. Technical Field

Example embodiments relate to a duty cycle correction circuit and method for correcting a duty cycle and a semiconductor device including the duty cycle correction circuit, and more particularly, to a duty cycle correction circuit and method of correcting for maintaining a predetermined duty cycle according to duty codes regardless of a change in external factors, and a semiconductor device having the duty cycle correction circuit.

2. Description of Related Art

In general, a semiconductor device having a high operating speed of a double data rate (DDR) or more uses both the rising edges and falling edges of a clock, and the duty cycle of the clock needs to be maintained at 50%. To keep the duty cycle constant, a duty cycle correction circuit may be used, and in particular, a digital duty cycle correction circuit that has a small static current and a wide correction range and rapidly performs correction is frequently used.

A duty cycle correction circuit adjusts a delay value of signal by controlling the driving capabilities of a p-type metal oxide semiconductor (PMOS) transistor and n-type metal oxide semiconductor (NMOS) transistor prepared therein. As a result, a duty cycle correction circuit corrects the distortion of a duty cycle within a predetermined delay adjustment range (i.e., amount of duty error that the error correction circuit can correct). Here, it is ideal that the PMOS transistors and the NMOS transistors have the same delay adjustment range (i.e., that each can correct the same amount of duty error). However, when the properties of the PMOS transistor and the NMOS transistor are changed during a process, the driving capabilities of the PMOS transistors and the NMOS transistors also vary, and the delay adjustment ranges of the PMOS transistors and the NMOS transistors are mismatched. Also, according to external factors such as a process, voltage, and temperature (PVT), the delay adjustment ranges of the PMOS transistors and the NMOS transistors may be mismatched. When the delay adjustment ranges of the PMOS transistors and the NMOS transistors are mismatched as mentioned above, the duty cycle of a signal output from the duty cycle correction circuit may be distorted.

### SUMMARY

Example embodiments provide a circuit and method for correcting a duty cycle capable of adjusting linearly the duty cycle of a clock within a predetermined range by reducing distortion of the duty of the clock caused by a mismatch between a pull-up driving capability and pull-down driving capability changed according to external factors such as a process, voltage, and temperature (PVT), and a semiconductor device having the circuit.

In one embodiment, a duty cycle correction circuit is disclosed. The duty cycle correction circuit includes a code generator configured to generate a first duty code and a second duty code for adjusting a duty cycle of a clock to a target duty cycle, and a duty cycle corrector including a plurality of inverter circuits connected in series and whose driving capabilities are adjusted in response to the first and second duty code, wherein the duty cycle corrector is configured to correct the duty cycle of the clock based on the driving capabilities of the inverter circuits and output a corrected clock.

In one embodiment, the first duty code and second duty code are inverted from each other, the first duty code is applied to a first inverter circuit of the plurality of inverter circuits and the second duty code is applied to a second inverter circuit of the plurality of inverter circuits, and the first inverter circuit and the second inverter circuit are adjacent each other.

In another embodiment a semiconductor device is disclosed. The semiconductor device includes a duty cycle correction circuit configured to generate a first and a second duty code for adjusting a duty cycle of a clock to a target duty cycle, adjust the driving capabilities of a plurality of inverter circuits in response to the first and second duty code, and adjust the duty cycle of the clock based on the driving capabilities of the inverter circuits to output a corrected clock. The semiconductor device further includes an internal circuit configured to perform an operation in synchronization with the corrected clock.

In a further embodiment, a method of correcting a duty cycle is disclosed. The method includes generating a first and a second duty code for adjusting a duty cycle of a clock to a target duty cycle, providing the first or second duty code to a plurality of inverter circuits connected in series and whose driving capabilities are adjusted in response to the first duty code or the second duty code, and correcting the duty cycle of the clock based on the adjusted driving capabilities of the inverter circuits to generate a corrected clock.

### BRIEF DESCRIPTION OF THE DRAWINGS

Example embodiments are described in further detail below with reference to the accompanying drawings. It should be understood that various aspects of the drawings may be exaggerated for clarity.

FIG. 1 is a block diagram of a circuit for correcting a duty cycle according to example embodiments.

FIG. 2 is a circuit diagram of a duty cycle corrector of FIG. 1, according to an exemplary embodiment.

FIG. 3A is a conceptual diagram illustrating operation of the circuit of FIG. 2, according to an exemplary embodiment.

FIG. 3B is another conceptual diagram illustrating operation of the circuit of FIG. 2, according to another exemplary embodiment.

FIG. 4 is an exemplary simulation waveform diagram in which a change in conventional corrected clock according to process, voltage, and temperature (PVT) is compared to a change in corrected clock according to example embodiments according to PVT.

FIG. 5 is an exemplary simulation waveform diagram in which a conventional corrected clock curve changing according to a duty code is compared to a corrected clock curve according to example embodiments changing according to the duty code.

FIG. 6 is a block diagram of a semiconductor device having a duty cycle correction circuit according to example embodiments.

### DETAILED DESCRIPTION OF THE EMBODIMENTS

Various example embodiments will now be described more fully with reference to the accompanying drawings in which some example embodiments are shown.

Detailed illustrative embodiments are disclosed herein. However, specific structural and functional details disclosed herein are merely representative for purposes of describing example embodiments. The systems and methods described herein may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the inventive concept. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the inventive concept is not limited to example embodiments described.

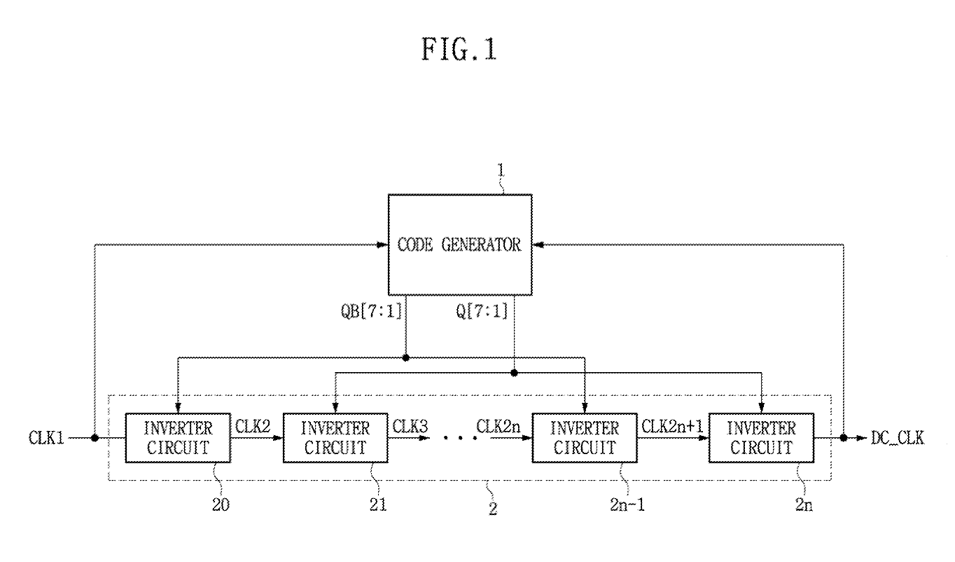

FIG. 1 is a block diagram of a duty cycle correction circuit according to example embodiments. As shown in FIG. 1, the duty cycle correction circuit includes a code generator 1 and a duty cycle corrector 2.

The code generator 1 receives a first clock CLK1, and generates duty codes QB[7:1] and Q[7:1] for adjusting the duty cycle of the first clock CLK1 to a target duty cycle. In one embodiment, the duty code QB[7:1] and the duty code Q[7:1] are inverted from each other. For example, when the duty code QB[7:1] is “0001111,” the duty code Q[7:1] is “1110000.” The code generator 1 can comprise one or more code generator circuits configured to generate a multi-bit code and an inverse multi-bit code.

The duty cycle corrector 2 adjusts the duty cycle of the first clock CLK1 in response to the duty codes QB[7:1] and Q[7:1] output from the code generator 1, corrects duty distortion, and outputs a corrected clock DC_CLK. The duty cycle corrector 2 includes two or more inverter circuits 20, 21, . . . , 2n-1, and 2n that are connected in series and whose driving capabilities are adjusted in response to the duty codes QB[7:1] and Q[7:1]. In one embodiment, the inverter circuits 20, 21, ..., 2n-1, and 2n have the same driving characteristics. For example, when p-type metal oxide semiconductor (PMOS) transistors of the inverter circuit 20 are manufactured to have a small channel size and thus the inverter circuit 20 has a small pull-up driving capability, the other inverter circuits 21, . . . , 2n-1, and 2n also have the same driving characteristic.

In one embodiment, the code generator 1 applies the duty codes QB[7:1] and Q[7:1] having values inverted from each other to each adjacent two of the inverter circuits 20, 21, . . . , 2n-1, and 2n, respectively. Also, the code generator 1 is fed back with the corrected clock DC_CLK and compares the corrected clock DC_CLK with the target duty cycle again. When the fed back corrected clock DC_CLK is not the same as the target duty cycle, the code generator 1 adjusts the duty codes QB[7:1] and Q[7:1] for adjusting the duty cycle of the corrected clock DC_CLK to the target duty cycle.

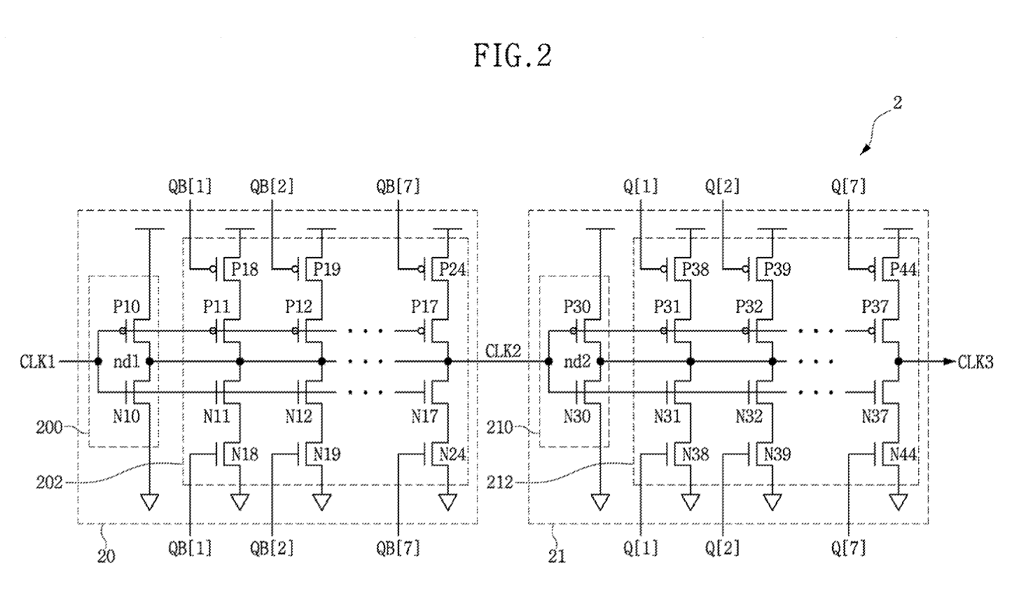

FIG. 2 is a circuit diagram of an exemplary duty cycle corrector of FIG. 1, according to an exemplary embodiment.

As shown in FIG. 2, the duty cycle corrector 2 includes the inverter circuits 20 and 21. For convenience, only the inverter circuits 20 and 21 are shown among the inverter circuits 20, 21, . . . , 2n-1, and 2n included in the duty cycle corrector 2 of FIG. 1.

The inverter circuit 20 includes a first inverter 200 that drives an output node nd1 in response to the first clock CLK1, and an inverter block 202 including a plurality of second inverters that each drive the output node nd1 in response to the first clock CLK1 and whose driving capabilities are adjusted according to the duty code QB[7:1]. The respective second inverters are selectively connected with a power supply voltage through PMOS transistors P18 to P24 that are turned on in response to the duty code QB[7:1], or selectively connected with a ground voltage through n-type metal oxide semiconductor (NMOS) transistors N18 to N24 that are turned on in response to the duty code QB[7:1]. In other words, in the inverter circuit 20, the first inverter 200 having a constant pull-up driving capability and a constant pull-down driving capability regardless of the duty code QB[7:1] and the second inverters whose pull-up driving capabilities and pull-down driving capabilities are adjusted in response to the duty code QB[7:1] drive the output node nd1 together, thereby generating a second clock CLK2.

In one embodiment, the PMOS transistors P11 to P17 respectively corresponding to bits of the duty code QB[7:1] have channels doubled in sequence and pull-up driving capabilities doubled in sequence (e.g., the channel size and pull-up driving capability of transistor P13 are twice that of the size and driving capability of transistor P12, which is twice that of transistor P11, etc.). Likewise, the NMOS transistors N11 to N17 respectively corresponding to bits of the duty code QB[7:1] have pull-down driving capabilities doubled in sequence.

The inverter circuit 21 includes a third inverter 210 that drives an output node nd2 in response to the second clock CLK2, and an inverter block 212 including a plurality of fourth inverters that each drive the output node nd2 in response to the second clock CLK2 and whose driving capabilities are adjusted according to the duty code Q[7:1]. The respective fourth inverters are selectively connected with the power supply voltage through PMOS transistors P38 to P44 that are turned on in response to the duty code Q[7:1], or selectively connected with the ground voltage through NMOS transistors N38 to N44 that are turned on in response to the duty code Q[7:1]. In other words, in the inverter circuit 21, the third inverter 210 having a constant pull-up driving capability and a constant pull-down driving capability regardless of the duty code Q[7:1], and the fourth inverters whose pull-up driving capabilities and pull-down driving capabilities are adjusted in response to the duty code Q[7:1] drive the output node nd2 together, thereby generating a third clock CLK3.

In one embodiment, the PMOS transistors P31 to P37 respectively corresponding to bits of the duty code Q[7:1] have channels doubled in sequence and pull-up driving capabilities doubled in sequence. Likewise, the NMOS transistors N31 to N37 respectively corresponding to bits of the duty code Q[7:1] may have pull-down driving capabilities doubled in sequence. As described above, the inverter circuits 20 and 21 may have the same constitution. Operation of the inverter circuit 20 will be described below as an example.

As the value of the duty code QB[7:1] increases, the pull-down driving capability of the inverter circuit 20 becomes superior to the pull-up driving capability of the inverter circuit 20. That is, there is an increase in delay of the second clock CLK2 through PMOS transistors and a decrease in delay of the second clock CLK2 through NMOS transistors. Thus, the length of the rising edges of the second clock CLK2 may gradually increase, and the length of the falling edges of the second clock CLK2 may gradually decrease. In other words, the logic high portion of the second clock CLK2 is reduced, and the duty cycle of the second clock CLK2 decreases. On the other hand, as the value of the duty code QB[7:1] decreases, the pull-up driving capability of the inverter circuit 20 becomes superior to the pull-down driving capability of the inverter circuit 20. That is, there is a decrease in delay of the second clock CLK2 through PMOS transistors and an increase in delay of the second clock CLK2 through NMOS transistors. Thus, the length of the rising edges of the second clock CLK2 may gradually decrease, and the length of the falling edges of the second clock CLK2 may gradually increase. In other words, the logic high portion of the second clock CLK2 increases, and the duty cycle of the second clock CLK2 increases. In this way, the inverter circuit 20 adjusts the duty cycle of the first clock CLK1 based on the changes achieved in the second clock CLK2. For example, an increase in the duty cycle of CLK2 effectively decreases the duty cycle of CLK1, and a decrease in the duty cycle of CLK2 effectively increases the duty cycle of CLK1.

Typically, it is substantially difficult for the second clock CLK2 that the inverter circuit 20 generates in response to the duty code QB[7:1] to have the target duty cycle. This is because the driving characteristics of the PMOS transistors P18 to P24 are not the same as those of the NMOS transistors N18 to N24, and it is difficult for the inverter circuit 20 to realize a duty cycle corresponding to the duty code QB[7:1]. For example, when the duty code QB[7:1] is the median “1000000,” the duty cycle of the first clock CLK1 should be adjusted to about 50%. However, when the pull-up driving capabilities of the PMOS transistors P18 to P24 are mismatched with the pull-down driving capabilities of the NMOS transistors N18 to N24, delay values of the PMOS transistors and delay values of the NMOS transistors are different from each other. Therefore, the duty of the first clock CLK1 is increased or reduced, and the duty cycle becomes greater or less than 50%. To correct such a duty distortion, the inverter circuit 21 having the same driving characteristics as the inverter circuit 20 is connected with the inverter circuit 20.

As discussed above, in one embodiment, the adjacent inverter circuits 20 and 21 have the same constitution. However, the duty codes QB[7:1] and Q[7:1] respectively applied to the inverter circuits 20 and 21 have values inverted from each other, and the inverter circuits 20 and 21 perform opposite operations. The first clock CLK1 alternately undergoes pull-up and pull-down processes while being inverted by the inverter circuits 20 and 21 in sequence. Thus, even if the pull-up driving capability and pull-down driving capability of each of the inverter circuits 20 and 21 are mismatched, the first clock CLK1 is distorted in opposite directions while being pulled up and down by the inverter circuits 20 and 21, and duty distortions caused by the inverter circuits 20 and 21 cancel each other.

In brief, in the duty cycle correction circuit according to example embodiments, the inverter circuits 20 and 21 having the same driving characteristics are connected in series, and the duty codes QB[7:1] and Q[7:1] having values inverted from each other are applied. Then, waveform distortions working in opposite directions in the inverter circuits 20 and 21 cancel each other, thereby correcting distortion of the duty of a clock. As shown in FIG. 1, the more inverter circuits are connected in series, the greater the distortion correction effect. In particular, when an even number of inverter circuits are connected, the improvement further increases.

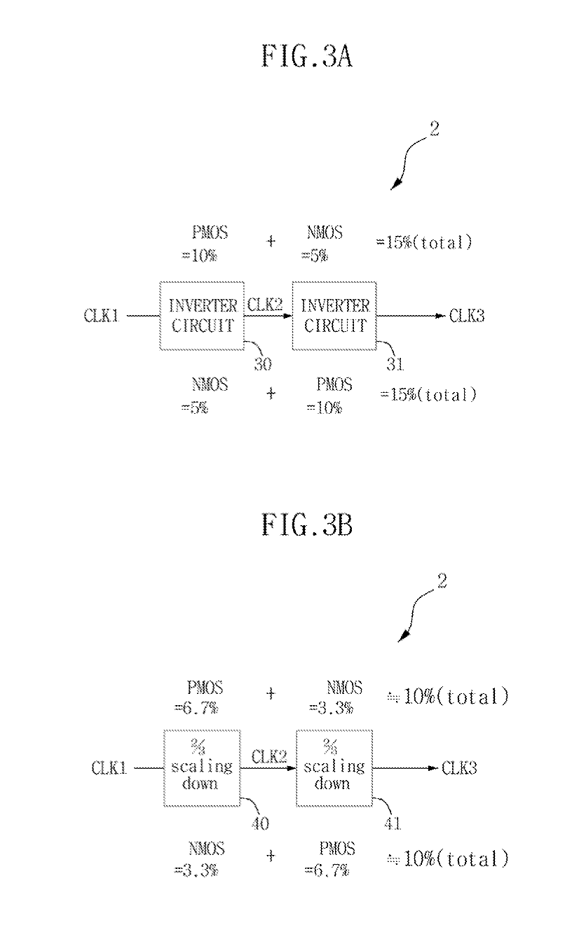

FIG. 3A is a conceptual diagram illustrating operation of FIG. 2, according to one exemplary embodiment.

For convenience, it is assumed that duty codes QB[7:1] and Q[7:1] are “0000000” and “1111111” respectively and PMOS transistors of inverter circuits 30 and 31 have a delay value of 10%, NMOS transistors have a delay value of 5%. However, these values are exemplary only, and other duty cover ranges may occur or other duty codes may be used.

Operation of the adjacent inverter circuits 30 and 31 connected in series will be described below with reference to FIG. 3A.

Rising edges of the first clock CLK1 are delayed through the PMOS transistors by 10% and through the NMOS transistors by 5%. Accordingly, rising edges of the first clock CLK1 are delayed through PMOS transistors of the inverter circuit 30 and NMOS transistors of the inverter circuit 31 by total delay value of 15%. However, falling edges of the first clock CLK1 are delayed through the NMOS transistors by 5% and through the PMOS transistors by 10%. Accordingly, falling edges of the first clock CLK1 are delayed through NMOS transistors of the inverter circuit 30 and PMOS transistors of the inverter circuit 31 by total delay value of 15%. Thus, rising edges and falling edges of the first clock CLK1 have same total delay values by the inverter circuits 30 and 31 and then a duty cycle of the first clock CLK1 is maintained constantly regardless of a mismatch in driving capabilities of the PMOS transistors and the NMOS transistors.

In this way, as the first clock CLK1 alternately undergoes the pull-up and pull-down processes through the combination of inverter circuits 30 and 31, a distortion by the inverter circuit 30 and a distortion by the inverter circuit 31 are canceled each other. Accordingly, a distortion of the duty cycle of the first clock CLK1 can be corrected regardless of a mismatch of driving capabilities of the PMOS transistors and the NMOS transistors.

FIG. 3B is another conceptual diagram illustrating operation of FIG. 2, according to one exemplary embodiment.

Inverter circuits 40 and 41 shown in FIG. 3B are scaled down by ⅓ from the inverter circuits 30 and 31 shown in FIG. 3A. In other words, PMOS transistors and NMOS transistors included in the inverter circuits 40 and 41 are set to have smaller channel sizes than those included in the inverter circuits 30 and 31 of FIG. 3A.

A delay adjustment range of the inverter circuits 30 and 31 is changed according to channel sizes of the PMOS transistors and the NMOS transistors. However, when the delay adjustment range of the inverter circuits 30 and 31 exceeds a target delay adjustment range, an unnecessary increase in layout area occurs. Thus, to equalize a delay adjustment range with the target delay adjustment range, the inverter circuits 40 and 41 are be scaled down.

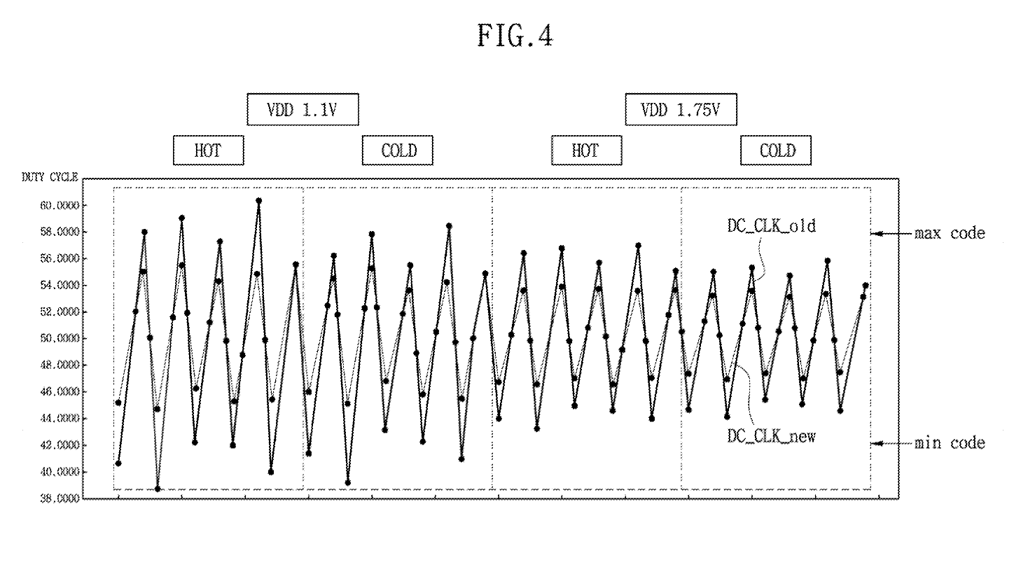

FIG. 4 is an examplary simulation waveform diagram in which a change in conventional corrected clock according to process, voltage, and temperature (PVT) is compared to a change in corrected clock according to example embodiments according to PVT.

Referring to a conventional corrected clock curve DC_CLK_old of FIG. 4, duty cycles corresponding to a max code and a min code of a duty code are irregularly changed according to a change in temperature (HOT and COLD) and power supply voltage (1.1 V and 1.75 V). In other words, the duty cycles corresponding to the max code and the min code of a duty code do not have constant values but have variable values according to a mismatch between the pull-up driving capability and pull-down driving capability of an inverter circuit.

On the other hand, a corrected clock curve DC_CLK_new of exemplary embodiments exhibits relatively constant duty cycles corresponding to the min code and the max code of a duty code in comparison with the conventional corrected clock curve DC_CLK_old. In other words, when a duty cycle correction circuit according to example embodiments is used, duty distortion caused by external factors is reduced, and it is possible to adjust the duty cycle of a corrected clock.

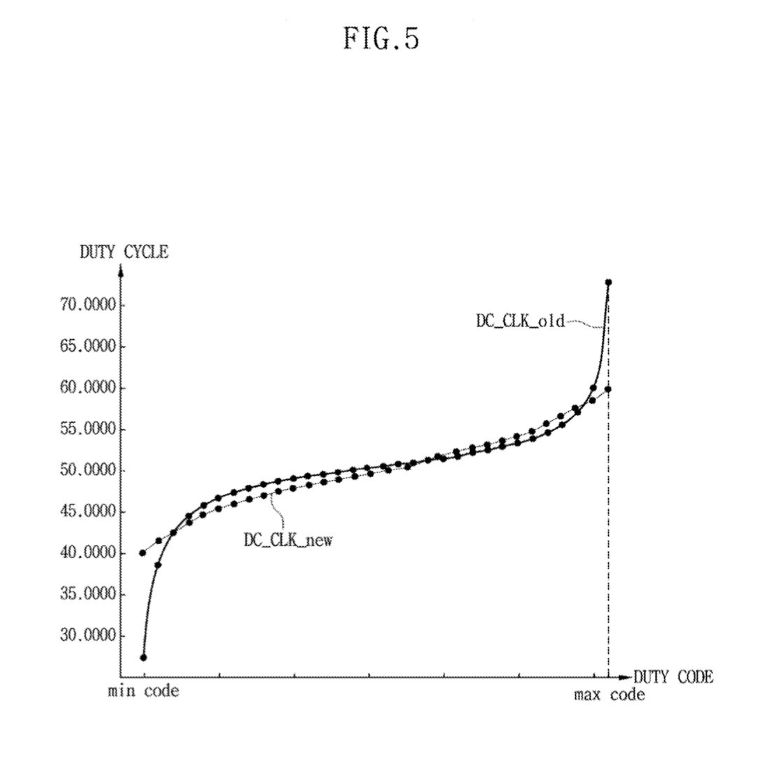

FIG. 5 is a simulation waveform diagram in which a conventional corrected clock curve DC CLK old changing according to a duty code and a corrected clock curve DC_CLK_new of example embodiments changing according to the duty code are compared.

Referring to FIG. 5, according to the conventional corrected clock curve DC_CLK_old, the duty cycle of a corrected clock remarkably varies as it approaches a min code and a max code of a duty code. Referring to FIG. 2, this is because a weak inverter is employed as a first inverter to prevent duty distortion caused by the first inverter that operates around the min code and the max code regardless of a duty code. As a result, the conventional corrected clock curve DC_CLK old is not linear, and the variance of the duty cycle according to a duty code has low resolution.

On the other hand, in example embodiments, adjacent inverter circuits cancel distortions, and a relatively strong inverter may be employed as the first inverter of each inverter circuit. Thus, inverter circuits have a constant driving capability using only the first inverters even at the min code and the max code. As a result, the corrected clock curve DC_CLK_new according to example embodiments is linear, and the variance of the duty cycle according to a duty code has high resolution.

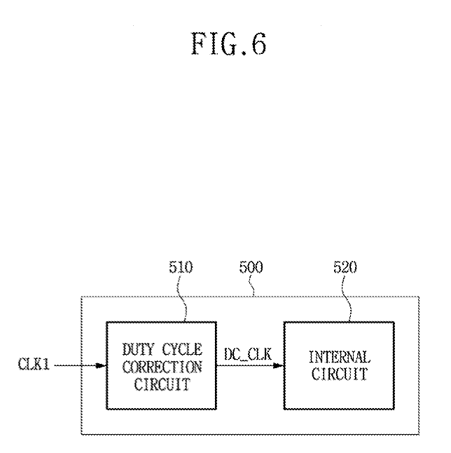

FIG. 6 is a block diagram of a semiconductor device having a duty cycle correction circuit according to example embodiments.

Referring to FIG. 6, a semiconductor device 500 includes a duty cycle correction circuit 510 and an internal circuit 520.

As described with reference to FIGS. 1 to 5, the duty cycle correction circuit 510 includes a code generator that generates a duty code for setting the duty cycle of the first clock CLK1 as a target duty cycle, and a duty cycle corrector including inverter circuits whose pull-up driving capabilities and pull-down driving capabilities are adjusted in response to the duty code.

Thus, the duty cycle correction circuit 510 adjusts the duty cycle of the first clock CLK1 in response to a duty code, and reduces duty distortion caused in a duty adjustment process to generate a corrected clock DC_CLK.

The internal circuit 520 includes a part or all of circuits in the semiconductor device 500, and performs an operation in synchronization with the corrected clock DC_CLK output from the duty cycle correction circuit 510.

As described above, a circuit and method for correcting a duty cycle according to example embodiments and a semiconductor device including the circuit according to example embodiments can linearly adjust the duty cycle of a clock within a predetermined duty cover range regardless of a change in external factors such as PVT.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this inventive concept as defined in the claims. For example, example embodiments can be applied to a measurement method for monitoring process variation in semiconductor equipment. In addition, the circuits and methods for correcting a duty cycle disclosed herein could be applied to other systems that employ clocks, such as different types of memory, microprocessors, and other integrated circuits. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A duty cycle correction circuit, comprising:
a code generator configured to generate a first duty code and a second duty code for adjusting a duty cycle of a clock to a target duty cycle; and
a duty cycle corrector including a plurality of inverter circuits connected in series and whose driving capabilities are adjusted in response to the first and second duty code, wherein the duty cycle corrector is configured to correct the duty cycle of the clock based on the driving capabilities of the inverter circuits and to output a corrected clock.

2. The duty cycle correction circuit according to claim 1, wherein the first duty code and the second duty code are inverted from each other, the first duty code is applied to a first inverter circuit of the plurality of inverter circuits and the second duty code is applied to a second inverter circuit of the plurality of inverter circuits, and the first inverter circuit and the second inverter circuit are adjacent each other.

3. The duty cycle correction circuit according to claim 1, wherein the duty cycle corrector adjusts a pull-up driving capability and a pull-down driving capability of the plurality of inverter circuits in response to the first and second duty code.

4. The duty cycle correction circuit according to claim 1, wherein the duty cycle corrector has an even number of the inverter circuits.

5. The duty cycle correction circuit according to claim 1, wherein each of the inverter circuits includes:
a first inverter configured to drive an output node in response to the clock; and
a plurality of second inverters configured to drive the output node in response to the clock and whose driving capabilities vary according to the first duty code or second duty code.

6. The duty cycle correction circuit according to claim 5, wherein the duty cycle corrector adjusts pull-up driving capabilities and pull-down driving capabilities of the second inverters of each of the inverter circuits according to the first and second duty code.

7. The duty cycle correction circuit according to claim 1, wherein the code generator is fed back with the corrected clock, and wherein the code generator adjusts the first and second duty code in response to the feedback in order to adjust a duty cycle of the corrected clock to the target duty cycle.

8. The duty cycle correction unit according to claim 1, wherein:
a first inverter circuit of the plurality of inverter circuits includes:
a first inverter configured to drive a first output node in response to the clock, and
a plurality of second inverters connected in parallel and whose driving capabilities are adjusted according to the first duty code, each configured to drive the first output node together in response to the clock, thereby generating a second clock on the first output node; and
a second inverter circuit of the plurality of inverter circuits is configured to receive the second clock, and further includes:
a third inverter configured to drive a second output node in response to the second clock, and
a plurality of fourth inverters connected in parallel and whose driving capabilities are adjusted according to the second duty code, each configured to drive the second output node together in response to the second clock.

9. The duty cycle correction circuit according to claim 8, wherein:
a first of the plurality of second inverters has a first driving capability, and each subsequent inverter of the plurality of second inverters has a driving capability double that of the previous inverter; and
a first of the plurality of fourth inverters has a second driving capability, and each subsequent inverter of the plurality of fourth inverters has a driving capability double that of the previous inverter.

10. A semiconductor device, comprising:
a duty cycle correction circuit configured to generate a first and a second duty code for adjusting a duty cycle of a clock to a target duty cycle, adjust the driving capabilities of a plurality of inverter circuits in response to the first and second duty code, and adjust the duty cycle of the clock based on the adjusted driving capabilities of the inverter circuits to output a corrected clock; and
an internal circuit configured to perform an operation in synchronization with the corrected clock.

11. The semiconductor device according to claim 10, wherein each adjacent two of the plurality of inverter circuits adjust a pull-up driving capability and a pull-down driving capability in response to the first duty code and the second duty code respectively, wherein the first duty code and the second duty code are inverted from each other.

12. The semiconductor device according to claim 10, wherein the duty cycle correction circuit has an even number of the inverter circuits.

13. The semiconductor device according to claim 10, wherein each of the inverter circuits includes:
a first inverter configured to drive an output node in response to the clock; and
a plurality of second inverters configured to drive the output node in response to the clock and whose driving capabilities vary according to the first duty code or the second duty code.

14. The semiconductor device according to claim 10, wherein the duty cycle correction circuit includes:
a code generator configured to generate the first and second duty code for adjusting the duty cycle of the clock to the target duty cycle; and
a duty cycle corrector configured to adjust the duty cycle of the clock by inverter circuits whose pull-up driving capabilities and pull-down driving capabilities are adjusted in response to the first and second duty code, and to output the corrected clock having the target duty cycle.

15. The semiconductor device according to claim 10, wherein:
a first inverter circuit of the plurality of inverter circuits includes:
a first inverter configured to drive an output node in response to the clock, and
a first inverter block including a plurality of pull-up transistors and a plurality of pull-down transistors; and
a second inverter circuit of the plurality of inverter circuits is configured to receive a second clock output from the first inverter circuit, and further includes:
a second inverter configured to drive an output node in response to the second clock, and
a second inverter block including a plurality of pull-up transistors and a plurality of pull-down transistors,
wherein the plurality of pull-up transistors of the first inverter block have the same driving capabilities as the plurality of pull-up transistors of the second inverter block, and
the plurality of pull-down transistors of the first inverter block have the same driving capabilities as the plurality of pull-down transistors of the second inverter block.

16. The semiconductor device according to claim 15, wherein:
each pull-up transistor and pull-down transistor of the first inverter block corresponds to a part of the first duty code, and each pull-up transistor and pull-down transistor of the second inverter block corresponds to a part of the second duty code.

17. A method of correcting a duty cycle, comprising:
generating a first and a second duty code for adjusting a duty cycle of a clock to a target duty cycle;
providing the first or second duty code to a plurality of inverter circuits connected in series and whose driving capabilities are adjusted in response to the first duty code or the second duty code; and
correcting the duty cycle of the clock based on the adjusted driving capabilities of the inverter circuits to generate a corrected clock.

18. The method according to claim 17, wherein the first duty code and the second duty code are inverted from each other and are applied to each adjacent two of the adjacent inverter circuits, respectively, such that the first duty code is applied to a first inverter circuit, and the second duty code is applied to a second inverter circuit that is adjacent to the first inverter circuit.

19. The method according to claim 17, wherein there are an even number of the inverter circuits.

20. The method according to claim 17, further comprising feeding back the corrected clock to adjust the first and second duty code for adjusting a duty cycle of the corrected clock to the target duty cycle.
